(19) United States
(12) Patent Application Publication
(10) Pub. No.: US 2019/0051811 A1
(43) Pub. Date: Feb. 14, 2019

(54) NANOFIBERS

(71) Applicant: SINGAPORE UNIVERSITY OF TECHNOLOGY AND DESIGN, Singapore (SG)

(72) Inventors: Rajasekaran Ganeshkumar, Singapore (SG); Kostiantyn V. Sopiha, Singapore (SG); Zhao Rong, Singapore (SG); Chin Wei Cheah, Singapore (SG); Wu Ping, Singapore (SG)

(21) Appl. No.: 16/085,813

(22) PCT Filed: Mar. 17, 2017
(86) PCT No.: PCT/SG2017/050135

§ 371 Date: Sep. 17, 2018

(30) Foreign Application Priority Data
Mar. 17, 2016 (SG) 10201602101R

(51) Int. Cl. H01L 41/08; D01D 5/00; D01F 1/10; D04H 1/4382; D04H 1/728; C04B 35/495

(52) U.S. Cl. CPC H01L 41/082; D01D 5/0038; C04B 35/495; D04H 1/4382; D04H 1/728; D01F 1/10

(57) ABSTRACT

The present invention relates to nanofibers. In particular, the present invention relates to potassium niobate nanofibers. In an aspect of the present invention, there is provided a method of preparing the nanofibers, the method comprising: (a) dissolving niobium chloride and potassium sorbate in a solvent to obtain a first solution; (b) removing chloride precipitates formed from the first solution; (c) adding a polymer, for example polymethylmethacrylate or polyvinylpyrrolidone to the solution to obtain a second spinnable solution; and (d) electrospinning the spinnable solution to produce the fibers. The application also discloses the application of such nanofibers in the manufacture of a humidity sensor device by sputtering a metal such as Tantalum on top of the nanofibers.

The present invention relates to nanofibers. In particular, the present invention relates to potassium niobate nanofibers and its application as a humidity sensor device.

Potassium niobate (KNbO₃), a ferroelectric compound with perovskite-type structure, has attracted considerable amount of attention due to their superior piezoelectric, pyroelectric and nonlinear optical properties[1,2]. Among several alkaline niobates, KNbO₃ is a prime candidate for lead-free, environmental friendly piezoelectric transducer and energy harvesting applications to replace widely used lead containing ferroelectrics[3,4]. In one dimensional (1D) nanoscale form, the applications for KNbO₃ can be greatly extended to emerging fields like environmental sensing and nano-electrical-mechanical Systems (NEMS) as nanoscale components[5].

Being a promising nanomaterial for numerous applications, various ways for preparing KNbO₃ (KNO hereafter) nanostructures have been investigated and developed. Liu et al, Kinomura et al and Magrez et al systematically studied the hydrothermal routes to produce KNO nanorods and nanowires respectively[6-9]. Pribošič et al used template crystallization of a precursor gel to synthesize KNO nanoneedles[10]. Several alternative ways such as microwave assisted hydrothermal, hydrothermal-assisted sol-gel method, solvothermal, molten-salt reaction, and modified solid-state synthesis etc., have been employed to prepare KNO nanostructures[11-15]. However, hydrothermal route demands very long reaction time (6-7 days) to obtain high quality KNO nanostructures[8,13]. While solid-state reactions face serious complications as they tend to form non-stoichiometric stable products due to potassium volatility and excessive reactivity with moisture[15]. Distinct from semiconductor nanowires, hydrothermally grown KNO nanowires are usually short (<10 μm) and randomly aligned which impede investigations and applications of these materials[3,6-9]. Despite progress in the ability to prepare 1D oxide nanostructures, no report concerning the synthesis of long, functional perovskite KNO nanostructures is available so far.

Among the nanosensors, the humidity detection and monitoring is important in fields such as weather, agriculture, industrial automation, medical and semiconductor researches[17-20]. In the past years, many detection techniques have been explored from old wet and dry bulb thermometry to modern capacitive, resistive moisture detectors[17]. The following are some of the desired features to improve the humidity sensing performance[19]: 1) transducer material 2) availability of suitable fabrication techniques and 3) free choice of device geometry. ABO₃-type complex metal oxide is extensively studied because of its stability and reliability in oxidizing and reducing atmospheres[15]. The bulk counterparts of AbO₃ in the application of humidity sensor have been widely reported before. However, the sensing properties are not perfect as they either lack in the sensitivity or the response and recovery times[21,22].

There is, therefore, a need for an improved nanosensor for measuring humidity.

The listing or discussion of an apparently prior-published document in this specification should not necessarily be taken as an acknowledgement that the document is part of the state of the art or is common general knowledge.

Any document referred to herein is hereby incorporated by reference in its entirety.

The present invention thus relates to ultra-long KNO nanofibers that may be synthesized using sol-gel based far-field electrospinning process. Electrospinning process is the simplest and most versatile technique capable of generating nanofibers that have high aspect ratio, controllable fiber diameter and precise chemical stoichiometric composition[16]. Our experimental results indicate electrospun KNO nanofibers are ultra-long, ˜100 nm in diameter, orthorhombic in phase and stable at room temperature (RT), which could be a critical breakthrough for deployment of these materials in nanosensors and nano-actuators.

Due to its bio-eco-compatibility, chemical stability and large surface to volume ratio, KNO nanofibers (perovskite ABO₃-type complex metal oxide) are explored as an active material for humidity sensors. Electrospinning is remarkably simple to generate thin KNO nanofibers providing the flexibility in the device geometry of the humidity nanosensor to attain the required dimensional efficiencies. To the best of our knowledge, this study is the first report on successful demonstration of a fast and highly sensitive humidity nanosensor based on KNO nanofibers for measuring relative humidity (RH) in a wide range of 15-95% in air at room temperature (25° C.). In addition to its excellent sensitivity, as-fabricated nanosensor exhibits good linearity, reproducibility and stability, demonstrating comparable performance among the best results of reported humidity nanosensors (see table 1 below).

In an aspect of the present invention, there is provided a method of preparing fibers, the method comprising: (a) dissolving niobium chloride and potassium sorbate in a solvent to obtain a first solution; (b) removing chloride precipitates formed from the first solution; (c) adding a polymer to the solution to obtain a second spinnable solution; and (d) electrospinning the spinnable solution to produce the fibers.

By “nanofiber”, it is meant to refer to any fiber that typically has a diameter of 100 nm or less. Having said that, the present invention need not be limited to dimensions and sizes of the nanofibers disclosed in this application. As such, it may include any type of fibers that may be produced from the claimed method.

The polymer used is dependent upon the choice of solvent that is used to dissolve the niobium chloride and potassium sorbate. The polymer may be any one selected from the group comprising: polyvinylpyrrolidone, poly(methyl methacrylate), cellulose acetate, polyacrylonitrile, polyvinyl alcohol and polyethylene oxide. In an embodiment, the solvent may be an alcohol. In a more specific embodiment, the alcohol may be any one selected from the group comprising: methanol, ethanol and 2-methoxyethanol dimethylformamide.

In various embodiments, the molar ratio between potassium and niobium after removing the chloride precipitates is about 1.

The electrospinning may be carried out by any such method known to the skilled person. IN various embodiments, the electrospinning is carried out by ejecting the spinnable solution from a plastic syringe at a constant feed rate of 0.60 ml/hour. Alternatively, any other types of ejection may be used apart from a plastic syringe. During such ejection, the electrospun fibers may be collected on a substrate. In various embodiments, the substrate may be a SiO2/Si substrate or an aluminium foil, or any such suitable substrate that acts as a suitable supporting structure.

In various embodiments, the syringe and the substrate is separated by a distance of about 13 cm. The applied electrical between the syringe and the substrate is 1.5 kV/cm.

The ejection of the spinnable solution, i.e. the production of the fibers can go on for any desired length of time to allow sufficient or a desired amount of fibers to collect on the surface of the substrate. In various embodiments, such collection time may be 2 minutes or 5 minutes, or anywhere between 2 to 5 minutes. The collection time, if desired, may be longer than 5 minutes to allow more fibers to collect on the substrate.

The method further comprises drying the electrospun fibers at 60° C. for 1 hour. In addition, in various embodiments, the dried electrospun fibers undergo a calcination process at 550° C. for 5 hours at a heating rate of 5° C. per minute in atmosphere.

In various embodiments, the first solution obtained in step (a) is magnetically stirred for 1 hour. The spinnable solution is magnetically stirred for 3 hours prior to electrospinning.

In another aspect of the present invention, there is provided a method of preparing a humidity sensor device, the method comprising: (a) obtaining a fiber according to the above aspect of the invention; and (b) sputtering a metal on top of the fiber to form interdigitated electrodes. The metal may be any one selected from the group comprising: aluminium, chromium, gold, molybdenum, platinum, silver, titanium.

The deposition of the tantalum may be carried out by any suitable method known to the skilled person. In an embodiment, the deposition is sputtering. Preferably, the sputtering is DC sputtering.

Therefore, it follows that the present invention also provides for an electrospun fiber that is obtained from the method above.

In the broadest sense of the invention, the electrospun fiber comprises potassium niobate and a polymer. The fiber is orthorhombic. The length of each fiber is about or greater than 500 μm, and the average diameter of the fiber is about 100 nm. Advantageously, a smaller diameter of the electrospun nanofibers leads to a high surface area to volume which makes it an excellent candidate for numerous applications such as ferroelectric sensors and energy harvesters, humidity sensors, photo-catalysis etc., where high surface area is desirable. To further increase the surface area, controlling the sol-gel composition, porous and particle decorated KNbO₃ nanofibers were successfully synthesized here. The present method allows to fabricate ultra-long KNbO₃ nanofibers (solid & porous) giving rise to high surface area which are highly significant in developing nanoscale devices.

In yet another aspect of the present invention, there is provided a humidity sensor device comprising fibers according to the above earlier aspects of the invention. The sensor is adapted to measure relative humidity of between 15-95% in atmospheric air at a room temperature of about 25° C.

In various embodiments, the fibers are composed of densely stacked grains of about 40 nm in size. The sensor device may further comprise a substrate for supporting the fibers. The substrate may be SiO2/Si wherein the thickness of the SiO2/Si substrate is about 2 μm and 285 nm respectively.

In various embodiments, tantalum is spluttered on top of the fibers to form interdigitated electrodes. In an embodiment, the tantalum layer is about 350 nm, and the interdigitated electrodes are spaced about 250 μm apart.

In various embodiments, the fibers are stacked along the direction of the fiber axis. The length of each fiber is about or greater than 500 μm, and the average diameter of the nanofiber may be between 100 nm to 500 nm. For example, when PMMA solution is used, the average diameter is around 300-500 nm while fibers from PVP solution ends up 100 nm.

In order that the present invention may be fully understood and readily put into practical effect, there shall now be described by way of non-limitative examples only preferred embodiments of the present invention, the description being with reference to the accompanying illustrative figures.

In the Figures:

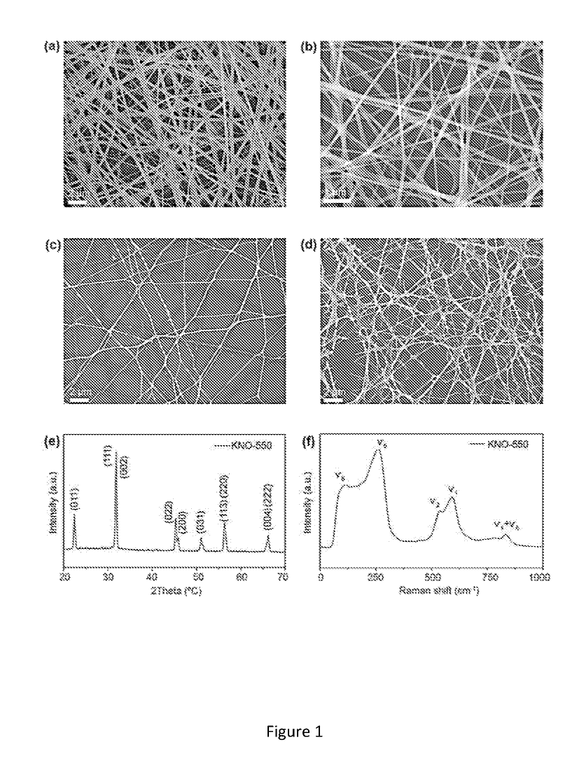

FIG. 1. (a) SEM image of KNO precursor fibers. (b) KNO fibers calcinated at 550° C. KNO fibers collected for (c) 2 mins (d) 5 mins. (e) XRD patterns and (f) Raman spectra of the KNO nanofibers calcinated at 550° C. for 5 h.

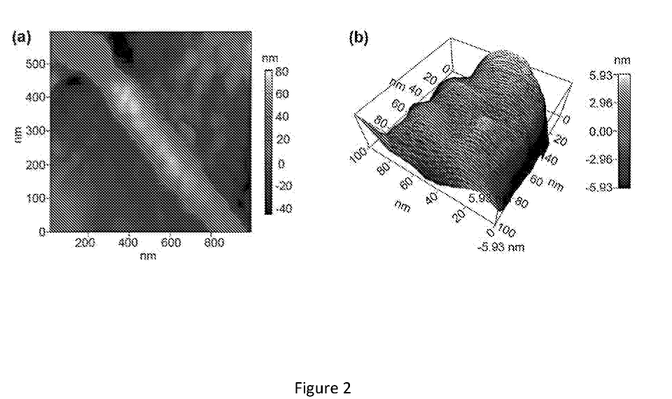

FIG. 2. (a) Topography of the single nanofiber using AFM. (b) 3D plot the topography showing grain size of the KNO-550 nanofiber.

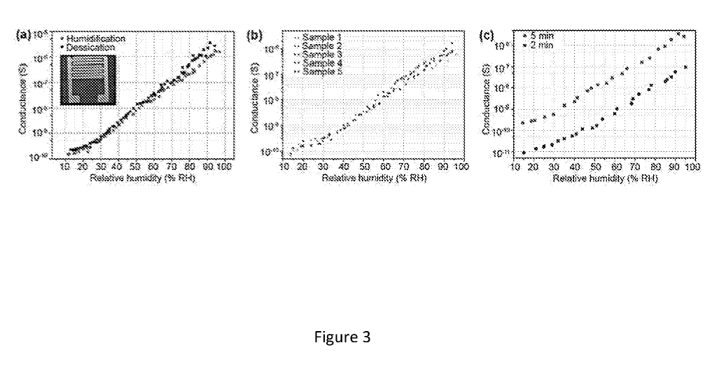

FIG. 3. (a) Conductance versus relative humidity during humidification and dehumidification cycle. Inset—as fabricated humidity nanosensor. (b) Sensitivity curves for five different samples based on KNO-550 nanofibers collected for 5 minutes (c) Comparison of sensitivity between 2-minute and 5-minute samples.

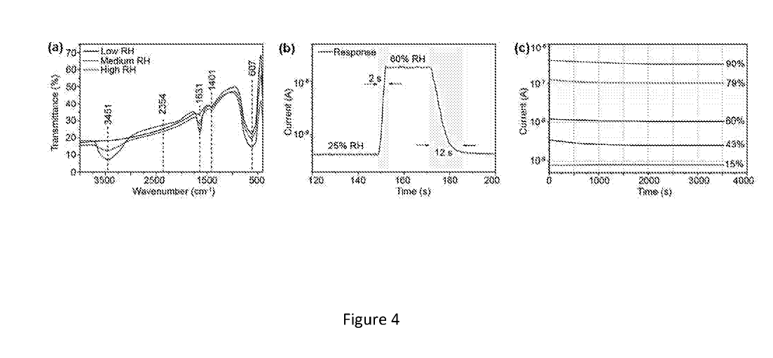

FIG. 4. (a) FTIR spectra of KNO-550 nanofibers at different RH environments (b) Response and recovery time of the nanosensor (c) Stability of the KNO-550 based nanosensor.

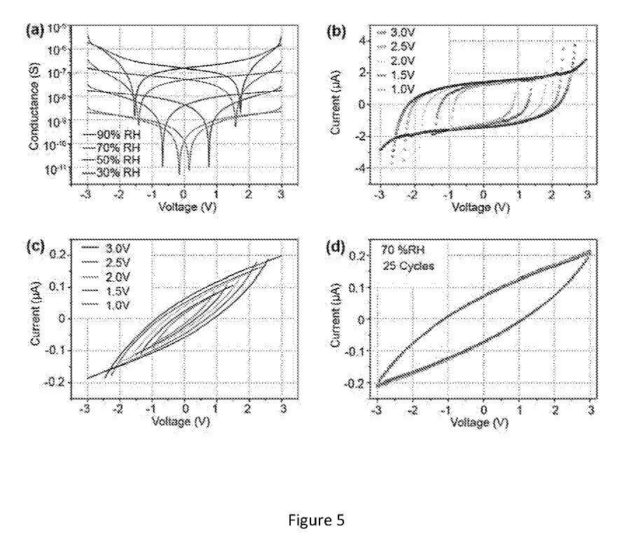

FIG. 5. (a) Absolute value of current versus voltage of humidity nanosensor in different RH atmosphere at RT. Hysteresis curves of the humidity nanosensor for varying bias voltage at (b) 90% RH (c) 70% RH. (d) Hysteresis curves of the humidity nanosensor when biased at 3 V for 25 continuous cycles at 70% RH.

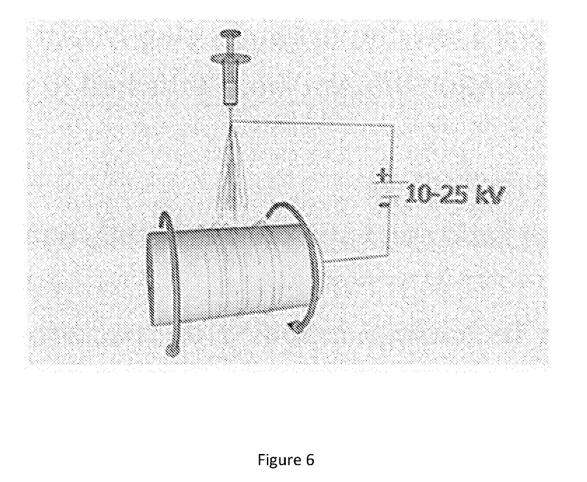

FIG. 6. Schematic illustration of electrospinning process.

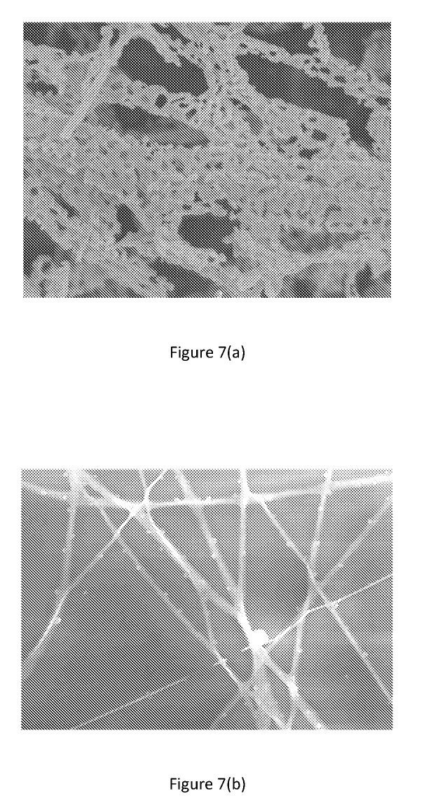

FIGS. 7(a) and (b) shows SEM images of the porous and decorated fibers respectively.

### EXAMPLE 1

Method and Material

Synthesis of KNbO₃ Nanofibers

FIG. 6 shows a schematic illustration of the electrospinning process. Electrospinning is a facile and cost-effective technique capable of generating nanofibers that are ultra-long, have controllable diameter and has precise chemical composition.

For the synthesis of KNbO₃ nanofibers, the precursor sol-gel was prepared by the following two step process. Firstly, 1 mmol of niobium chloride (0.27 g, >98%) and 6 mmol of potassium sorbate (0.907 g, >99%) were dissolved in methanol (4 ml) and the solution was magnetically stirred for 1 h at RT. During the mixing, color of the solution changes from fully transparent to white gradually, indicating the formation of potassium chloride precipitates which can be explained by the equation given below:

NbCl₅+6C₆H₇KO₂ [symbol] 5KCl↓L+(Nb⁵⁺+K⁺+6C₆H₇O₂⁻)ᵢₙ_{_}ₛₒₗᵤₜᵢₒₙ

This mixture was centrifuged for 5 min at 4000 rpm to remove the solid precipitates from the solution. XRD analysis of the obtained precipitates confirms that they are predominantly potassium chloride crystals. After the removal of chloride particles, the remaining solution turns slightly yellowish and the molar ratio between potassium and niobium approximately equals to 1. Secondly, PVP (0.533 g, >99%, MW=1,300,000) and 2-methoxyethanol (2.66 ml, 98%) were added to the existing solution to maintain the viscosity and ionic concentration favorable for electrospinning process. The mixture was further magnetically stirred for 3 hours at room temperature (about 25° C.) to obtain a homogenous KNO precursor solution.

During electrospinning process, the precursor solution was ejected from a plastic syringe at a constant feeding rate of 0.60 ml h⁻¹. The syringe and the collector was separated at a distance of 13 cm apart and the applied electrical between them was 1.5 kV cm⁻¹. The nanofibers were collected on to SiO₂ covered silicon substrate and dried at 60° C. for 1 h, followed by calcination process. The as-spun fibers were calcined at 550° C. at a heating rate of 5° C./min in atmosphere which are abbreviated to be KNO-550, respectively. All chemicals were purchased from Sigma-Aldrich and the measurements were carried out on calcined nanofibers.

The table below shows the amount and molecular weight of polymers used to obtain solid and porous KNbO₃ nanofibers abbreviated as KNO-S and KNO-P respectively.

| Fiber | | | Molecular | |
|---|---|---|---|---|
| morphology | Polymer | Amount | weight | Solvent |
| Solid KNO-S | Polyvinylpyrrolidone, | 0.4 g | 1,300,000 | 3 ml of |
| | PVP | | | 2-methoxyethanol |
| Porous KNO-P | Poly(methyl | 0.8 g | 120,000 | 3 ml of |
| | methacrylate), | | | Dimethylformamide |
| | PMMA | | | |

FIGS. 7(a) and (b) shows SEM images of the porous and decorated fibers respectively.

Characterization of KNbO₃ Nanofibers

Surface morphology and geometry of the KNO nanofibers were inspected using JEOL JSM7600F field-induced scanning electron microscope (FE-SEM) and Oxford Instruments MFP-3D was used for Atomic Force Microscopy. Elemental analysis (EDX) was performed using Oxford Instruments X-Max-50 silicon drift detector embedded in the FE-SEM system. Crystal structure of the as-synthesized nanofibers was analyzed using Bruker D8 advance XRD system (Cu Kα). Raman spectra of the KNO nanofiber samples were obtained using Witec Alpha300M Raman System.

Fabrication of the Humidity Nanosensor

Humidity nanosensor was fabricated based on KNO-550 nanofibers collected on SiO₂/Si substrate. Tantalum was sputtered on top of the fibers to form interdigitated electrodes (IDES) using DC sputtering (AJA Orion 5) to build the humidity nanosensor. Final device structure of the humidity sensor is Si (2 μm)/SiO₂ (285 nm)/KNO nanofibers/Ta (350 nm). The device dimensions are 2 cm×2 cm and IDE spacing of the sensor is 250 μm. The collection time was controlled to obtain samples with different density of nanofibers on the substrate. Two different humidity sensors based on 2-minute and 5-minute collection time was fabricated.

Characterization of the Humidity Nanosensor.

The humidity nanosensor is placed inside the testing chamber with two inlets to introduce dry and humid air respectively. During humidity sensor testing, IDE electrodes are connected to the Keithley 6430 Sub-Femtoamp Remote Source meter for measuring sensor response with respect to the change in relative humidity of the testing chamber which is monitored using commercial humidity sensor (Sensirion SHT21). The reference sensor from Sensirion uses a capacitor to sense humidity. Its dielectric is realized through a polymer, which absorbs or desorbs water depending on the ambient humidity. The electrodes are realized with an interdigitated electrode structure. The reference sensor was biased at 3.3 V and the response time was 8 s from 10% to 63% RH [23]. The humidity control was achieved by passing both humid and dry air at various flow rates, while the total flow remains fixed at 0.5 l/min.

Results and Discussion

KNbO₃ Nanofiber Phase and Morphology

The SEM micrographs (see FIGS. 1a-d) show that the fibers are non-woven and continuous. After calcination, KNO nanofibers are ultra-long in length ranging from 500 microns to several centimeters, while the average diameter of the fiber is approximately 100 nm. In alternative embodiments, the average diameter of the nanofiber may be between 100 nm to 500 nm. For example, when PMMA solution is used, the average diameter is around 300-500 nm while fibers from PVP solution ends up 100 nm. Presence of pure KNO with proper stoichiometry is confirmed by the EDX. The KNO nanofiber crystal structures were investigated using XRD analysis which showed that samples have perovskite structure (JCPDS card no. 32-822). As shown in FIG. 1e, there is a distinct diffraction peak appearing for the KNO-550 samples and the typical peak split (002 and 200 planes at 44° to) 46° indicates the formation of orthorhombic KNO nanofibers.

FIG. 1f shows the Raman spectra of the KNO nanofibers and the characteristic peaks at 280 cm⁻¹ (υ5), 597 cm⁻¹ (υ1) and 830 cm⁻¹ corresponding to the vibrational modes of NbO₆ octahedron. This implies the formation of perovskite—orthorhombic structure which is in agreement with the XRD profiles. Also, we observe that characteristic peak (u5) shifts to higher wave numbers from 256 cm⁻¹ to 280 cm⁻¹ as the temperature increases implying lattice distortion of KNO crystals at higher annealing temperature[24].

Furthermore, surface morphology of the nanofiber was investigated using contact mode of an atomic force microscopy. By scanning the tip across the sample area of 500 nm×500 nm, the topography of the fibers was obtained. FIG. 2a indicate(s) that the nano-grains are stacked to each other in one dimension to form the nanofiber. The grain size of KNO-550 is approximately 40 nm as can be seen from the 3D plot of the AFM topography image of 100 nm×100 nm sample area (see figure. 2b). Being an ABO₃ metal oxide with higher surface to volume ratio (SEM micrographs) and grainy structures (AFM scans) may make these ultra-long KNO nanofibers a good candidate for nanosensor applications[24,25].

KNbO₃ Nanofiber Based Humidity Nanosensor Characteristics

(a) Sensing Performance

Absorption of gases is expected to improve with smaller grain size, thus improving the sensing capability and sensitivity of the sensor[20]. KNO nanofibers calcinated at 550° C. have average grains of 40 nm in size when measured using AFM scans (see figure. 2) thereby giving rise to an increased area of grain boundary compared to the nanofibers calcinated at higher temperatures. Thus, humidity nanosensor was fabricated based on KNO-550 nanofibers collected on SiO₂/Si substrate. To evaluate the humidity sensing properties of the fabricated device, we measured the variation in nanosensor's electrical characteristics at room temperature with varying relative humidity (RH). The dependence of conductance on the RH for KNO-550 nanofibers collected for 5 minutes is shown in FIG. 3a. When the KNO-550 sample is biased at 3 V, the conductance increases dramatically from 1.5×10⁻¹⁰ J to 4×10⁻⁶ [symbol] (4 orders of magnitude) while RH values vary from 15% to 95% at room temperature respectively. When sensors based on 2-minute collection time were subjected to test for its humidity sensing properties, the conductance values changed from 9×10⁻¹² to 7.6×10⁻⁸ for the same RH range. FIG. 3c shows the change in conductance for 2-minute and 5-minute samples with respect to RH, which suggests that the change in density of the nanofibers collected on the substrate does not affect the sensitivity of the sensor significantly. For each type of sensors, several samples were fabricated and sensing performance was tested. FIG. 3b shows the sensitivity for the humidity sensors based on KNO-550 collected for 5 minutes, showing same sensitivity values. The results directly confirm the excellent consistency of the humidity sensors. Table 1 shows the sensitivity of KNO nanofibers for change in relative humidity is higher when compared to existing reports on humidity sensors based on ZnO, TiO₂ and BaTiO₃ nano-materials. The sensing results were largely stable and the error percentage for conductance values between humidification and desiccation cycles were very close as shown in FIG. 3a, suggesting good reproducibility and stability.

(b) Sensing Mechanism

The humidity sensitivity observed is attributed to large surface area, grain size and distribution and number of grain boundaries of the KNO nanofibers as these properties facilitates the easy adsorption of water molecules on the surface of the nanosensor[21,26]. When these nanofibers are exposed to humid air, few water molecules are chemisorbed at the neck of the crystalline grains and on the grain surface. This interaction is accompanied with a dissociative mechanism of water molecules to form hydroxyl groups. KNO-550 due to its large surface to volume ratio immensely helps the dissociated hydroxyl group (OH⁻) to interact with metal cations (K⁺) to form KOH, thus providing mobile protons (H⁺). These protons migrate from site to site on the surface leading to increased conductivity in the material which is in agreement with similar nanofiber based humidity sensors reported earlier[27]. At environment with higher humidity levels, after the surface area is completely covered by the chemisorption, subsequent water molecules are physisorbed on the existing hydroxyl layer. When RH is getting higher, the physisorption continues to increase and large amount of water molecules are adsorbed on the grain boundaries and flat surfaces, mobile protons becomes dominant carrier responsible for the electrical conductivity[26,27].

Fourier Transform infrared spectroscopy (FTIR) characterization of KNO-550 nanofibers was carried out to understand the surface chemistry of the nanofibers when subjected to different RH environments and possibly explain the sorption mechanism. The nanofibers were equilibrated at each RH environment for 1 hour before loading the sample for FTIR characterization and spectra was obtained as shown in FIG. 4a. The strong band centered at 607 cm⁻¹ represents the O—Nb—O stretching vibration, which is attributed to the corner shared NbO₆ octahedron[28,29]. The absorption bands at 1631 and 3451 cm⁻¹ can be assigned to H₂O adsorbed on the surface of the nanofibers[30]. In particular, the characteristic absorption between 3200-3600 cm⁻¹ can be seen increasing with the increase in humidity. The strong and broad peaks confirm the stretching and H-bonding with the surface of the nanofibers associated with the adsorption of water molecules. Once the sample is heated to dry, this peaks disappears.

(c) Sensor Response & Recovery Time

From FIG. 4b, the nanosensor displays an impressive response time of ˜2 s, as well as rapid recovery time of ˜10 s when the relative humidity in the chamber is switched from 25% to 60% then back to 25%. This result indicates that the humidity sensing behavior of the KNO nanofibers should be attributed to physisorption of water molecules and conductivity is dominated by the mobile protons driven by the electric field. Excellent response and recovery time can be attributed to the greatly reduced interfacial area between the sensing active region of the nanofibers and the underlying substrate when compared to thin films and nano particles[21]. To test the stability of the KNO-550 nanofiber sensors, they were exposed in five different RH environments for 1 hour. As observed in FIG. 4c, the conductance had no obvious deviation, suggesting prominent stability.

TABLE 1
Sensing performance of reported humidity sensors
based on semiconductor nanostructures.

| | | Response | Recovery time | |
|---|---|---|---|---|
| Material | Sensitivity | time (s) | (s) | Reference |
| SnO₂ nanowires | 33 | 120-170 | 20-60 | [17] |
| LiCl doped TiO₂ | ~10³ | 3 | 7 | [18] |
| nanofiber | | | | |
| ZnO nanowires | 5400 | 3 | 30 | [20] |
| BaTiO₃ nanofibers | ~10² | 4 | 5 | [22] |
| KNbO₃ nanofibers | 4 × 10⁴ | 2 | 10 | Present |
| | | | | invention |

Table 1 lists the room temperature performance of reported resistance-type humidity sensors based on other semiconductor nanostructures. The sensitivity of the humidity nanosensor based on KNO-550 is higher than other kinds of sensing materials. Moreover, the response time is comparable to ZnO nanowires and TiO₂ nanofibers and shorter than SnO₂ nanowires and BaTiO₃ nanofibers.

(d) Hysteresis Versus Relative Humidity

From FIG. 5a, it is evident that the ferroelectric coercive field increases as relative humidity increases. At higher humidity, non-linear dielectric property of KNO nanofiber becomes dominant (wider hysteresis loop), as the dielectric response induced by water adsorption is found to be very sensitive to the amount of water molecules on adsorptive layer of the nanofiber surface. At 90% RH, the hysteresis loop is obtained (see FIG. 5b) which indicates that coercive field is substantially higher than the field observed at 70% RH (see FIG. 5c). This variation in coercive field at 90% RH could be ascribed to the large number of water molecules covering the surface of the KNO nanofibers negatively influencing the reorientation of the ferroelectric dipoles. This behavior affects the logarithmic dependence of resistivity with respect to RH if the sensor. However, when sensor's bias voltage increases (˜3V), strong enough electric field helps to reduce the influence of the coercive field and it may improve the charge carrier velocity leading to the best linear response on conductance at higher RH (see FIG. 3a). As the sensor hysteresis has a wide loop, the repeatability of the loops was tested as shown in FIG. 5d. From several runs, the loop is repeatable, which would help in designing a stable calibration algorithm during practical usage of these nanosensors.

### CONCLUSION

Here, high-quality perovskite—orthorhombic KNbO₃ nanofibers were synthesized via electrospinning method using sol-gel precursor. After calcination at 550° C., the nanofibers were continuous with an average diameter of 100 nm and composed of densely stacked grains of about 40 nm in size. For the first time, resistive type humidity nanosensor based on as-synthesized KNO nanofibers was fabricated. The logarithmic dependence of conductance at different biasing conditions was investigated and compared with an off-the-shelf commercial humidity sensor. When biased at 3 V, the nanosensor exhibited excellent sensing characteristics: sensitivity of 4 orders in magnitude with respect to the varying relative humidity (15%-95%), faster response (2 s) & recovery (10 s), good linearity and reproducibility. Our findings on variations in coercive field with respect to relative humidity suggests that devices based on 1D KNO material should be encapsulated to avoid change in non-linear dielectric property at higher humidity levels for desired device performance. Moreover, this successful synthesis and demonstration of very high aspect ratio nanofibers would enable widespread applications of KNbO₃ materials in photo catalysis, non-linear optical and ferroelectric devices such as flexible optoelectronics and nanogenerators.

By virtue of the non-toxicity, high Tc, non-linear optical and ferroelectric properties, one dimensional (1D) potassium niobate (KNbO3) may enable the development of numerous nanoscale devices. Despite the progresses in 1D perovskite materials, preparing high aspect ratio KNbO3 nanostructures is still a concern. This invention presents the successful synthesis of ultra-long KNbO3 nanofibers using a simple sol-gel assisted far-field electrospinning process. At optimized conditions, centimeters long, orthorhombic KNbO3 nanofibers with an average diameter of 100 nm have been obtained. The nanofibers are composed of uniform grains densely stacked along the direction of nanofiber axis. Due to large surface-to-volume ratio, a high sensitive humidity nanosensor based on KNbO3 nanofibers displaying a logarithmic-linear dependence behavior of the conductance with the relative humidity (RH) was demonstrated. The conductance increases dramatically from 10-10 [symbol] to 10-6 [symbol] while RH varies from 15% to 95% at room temperature. In addition, the nanosensor exhibits excellent sensing performance, including ultrafast response (≤2 s) and recovery time 10 s), good linearity and reproducibility. Furthermore, the change in ferroelectric coercivity with respect to the RH and its effect in the sensing behaviour were unveiled. The work here could enable broad applications in the fields of environmental sensing and nano-electrical-mechanical systems.

Other potential applications include:
Piezoelectric energy harvesters
Ultrasound transducers
Non-linear optical devices—second harmonic generation
Flexible and wearable electronics
Photo-catalysis—dye degradation, water splitting (H₂ generation)

Whilst there has been described in the foregoing description preferred embodiments of the present invention, it will be understood by those skilled in the technology concerned that many variations or modifications in details of design or construction may be made without departing from the present invention.

### REFERENCES

[1] Zgonik M, Schlesser R, Biaggio I, Voit E, Tscherry J and Gunter P 1993 Materials constants of KNbO3 relevant for electro- and acousto-optics J. Appl. Phys. 74 1287
[2] Nakayama Y, Pauzauskie P J, Radenovic A, Onorato R M, Saykally R J, Liphardt J and Yang P 2007 Tunable nanowire nonlinear optical probe. Nature 447 1098-101
[3] Jung J H, Chen C Y, Yun B K, Lee N, Zhou Y, Jo W, Chou L J and Wang Z L 2012 Lead-free KNbO3 ferroelectric nanorod based flexible nanogenerators and capacitors Nanotechnology 23 375401
[4] Yang Y, Jung J H, Yun B K, Zhang F, Pradel K C, Guo W and Wang Z L 2012 Flexible pyroelectric nanogenerators using a composite structure of lead-free KNbO(3) nanowires Adv Mater 24 5357-62
[5] Saito Y, Takao H, Tani T, Nonoyama T, Takatori K, Homma T, Nagaya T and Nakamura M 2004 Lead-free piezoceramics. Nature 432 84-7
[6] Liu J-F, Li X-L and Li Y-D 2003 Synthesis and characterization of nanocrystalline niobates J. Cryst. Growth 247 419-24
[7] Kumada N, Kyoda T, Yonesaki Y, Takei T and Kinomura N 2007 Preparation of KNbO3 by hydrothermal reaction Mater. Res. Bull. 42 1856-62
[8] Magrez a, Vasco E, Seo J W, Dieker C, Setter N and Forro L 2006 Growth of Single-Crystalline KNbO 3 Nanostructures J. Phys. Chem. B 110 58-61
[9] Kim S, Lee J H, Lee J, Kim S W, Kim M H, Park S, Chung H, Kim Y I and Kim W 2013 Synthesis of monoclinic potassium niobate nanowires that are stable at room temperature J Am Chem Soc 135 6-9
[10] Pribošič I, Makovec D and Drofenik M 2005 Formation of nanoneedles and nanoplatelets of KNbO3 perovskite during templated crystallization of the precursor gel Chem. Mater. 17 2953-8
[11] Paula A J, Parra R, Zaghete M A and Varela J A 2008 Synthesis of KNbO3 nanostructures by a microwave assisted hydrothermal method Mater. Lett. 62 2581-4
[12] Amini M M and Mirzaee M 2009 Effect of solvent and temperature on the preparation of potassium niobate by hydrothermal-assisted sol-gel processing Ceram. Int. 35 2367-72
[13] Wang K, Liu Z, Shen G and Lu P 2012 Enhanced anisotropy of the nonlinear absorption in the individual Au nanoparticles functionalized KNbO3 sub-microwire. Opt. Express 20 24209-17
[14] Xu C Y, Zhen L, Yang R and Zhong L W 2007 Synthesis of single-crystalline niobate nanorods via ion-exchange based on molten-salt reaction J. Am. Chem. Soc. 129 15444-5
[15] Chaiyo N, Ruangphanit A, Muanghlua R, Niemcharoen S, Boonchom B and Vittayakorn N 2011 Synthesis of potassium niobate (KNbO3) nano-powder by a modified solid-state reaction J. Mater. Sci. 46 1585-90
[16] Li D and Xia Y 2004 Electrospinning of Nanofibers: Reinventing the Wheel? Adv. Mater. 16 1151-70
[17] Kuang Q, Lao C, Wang Z L, Xie Z and Zheng L 2007 High-Sensitivity Humidity Sensor Based on a Single SnO 2 Nanowire 6070-1
[18] Li Z, Zhang H, Zheng W, Wang W, Huang H, Wang C, MacDiarmid A G and Wei Y 2008 Highly sensitive and stable humidity nanosensors based on LiCI doped TiO2 electrospun nanofibers J. Am. Chem. Soc. 130 5036-7
[19] Farahani H, Wagiran R and Hamidon M N 2014 Humidity sensors principle, mechanism, and fabrication technologies: a comprehensive review. Sensors (Basel). 14 7881-939
[20] Xu J, Pan Q Shun Y and Tian Z 2000 Grain size control and gas sensing properties of ZnO gas sensor Sensors Actuators B Chem. 66 277-9
[21] He Y, Zhang T, Zheng W, Wang R, Liu X, Xia Y and Zhao J 2010 Humidity sensing properties of BaTiO3 nanofiber prepared via electrospinning Sensors Actuators B Chem. 146 98-102
[22] Wang L, He Y, Hu J, Qi Q and Zhang T 2011 DC humidity sensing properties of BaTiO3 nanofiber sensors with different electrode materials Sensors Actuators, B Chem. 153 460-4
[23] Sensirion Sensirion—Humidity & Temperature Sensors
[24] Chen H, Zhang Y and Lu Y 2011 Nanoscale potassium niobate crystal structure and phase transition Nanoscale Res Lett 6 530
[25] Ge H, Huang Y, Hou Y, Xiao H and Zhu M 2014 Size dependence of the polarization and dielectric properties of KNbO3 nanoparticles RSC Adv. 4 23344
[26] Rubinger C P L, Calado H D R, Rubinger R M, Oliveira H and Donnici C L 2013 Characterization of a sulfonated polycarbonate resistive humidity sensor Sensors (Switzerland) 13 2023-32
[27] Zhang Y, Pan X, Wang Z, Hu Y, Zhou X, Hu Z and Gu H 2015 Fast and highly sensitive humidity sensors based on NaNbO3 nanofibers RSC Adv. 5 20453-8
[28] Huan Y, Wang X, Hao W and Li L 2015 Enhanced photocatalysis activity of ferroelectric KNbO₃ nanofibers compared with antiferroelectric NaNbO₃ nanofibers synthesized by electrospinning RSC Adv. 5 72410-5
[29] Zhang T, Zhao K, Yu J, Jin J, Qi Y, Li H, Hou X and Liu G 2013 Photocatalytic water splitting for hydrogen generation on cubic, orthorhombic, and tetragonal KNbO3 microcubes. Nanoscale 5 8375-83
[30] Silverstein, Robert M; Fracias X, Webster; David J, Kiemle; David L B 1981 Spectrometric Identification of Organic Compounds (New York: John Wiley and Sons)

1. A method of preparing fibers, the method comprising:
(a) dissolving niobium chloride and potassium sorbate in a solvent to obtain a first solution;
(b) removing chloride precipitates formed from the first solution;
(c) adding a polymer to the solution to obtain a second spinnable solution; and
(d) electrospinning the spinnable solution to produce the fibers.

2. The method according to claim 1, wherein the polymer is any one selected from the group comprising: polyvinylpyrrolidone, poly(methyl methacrylate), cellulose acetate, polyacrylonitrile, polyvinyl alcohol and polyethylene oxide.

3. The method according to claim 1, wherein the solvent is an alcohol.

4. The method according to claim 3, wherein the alcohol is any one selected from the group comprising: methanol, ethanol and 2-methoxyethanol dimethylformamide.

5. The method according to claim 1, wherein the molar ratio between potassium and niobium after removing the chloride precipitates is about 1.

6. The method according to claim 1, wherein the electrospinning is carried out by ejecting the spinnable solution from a plastic syringe at a constant feed rate of 0.60 ml/hour.

7. The method according to claim 1, wherein the electrospun fibers are collected on a substrate.

8. The method according to claim 7, wherein the syringe and the substrate is separated by a distance of about 13 cm.

9. The method according to claim 8, wherein the applied electrical between the syringe and the substrate is 1.5 kV/cm.

10. The method according to claim 7, wherein the substrate is a SiO2/Si substrate or an aluminium foil.

11. The method according to claim 7, wherein the collection time for collecting the fibers on the substrate is between 2 to 5 minutes.

12. The method according to claim 1, further comprising drying the electrospun fibers at 60° C. for 1 hour.

13. The method according to claim 12, wherein the dried electrospun fibers undergo a calcination process at 550° C. for 5 hours at a heating rate of 5° C. per minute in atmosphere.

14. The method according to claim 1, wherein the first solution obtained in step (a) is magnetically stirred for 1 hour.

15. The method according to claim 1, wherein the spinnable solution is magnetically stirred for 3 hours prior to electrospinning.

16. A method of preparing a humidity sensor device, the method comprising:
(a) obtaining a fiber according to any one of claims 1 to 15; and
(b) sputtering a metal on top of the fiber to form interdigitated electrodes.

17. The method according to claim 16, wherein the metal is any one selected from the group comprising: aluminium, chromium, gold, molybdenum, platinum, silver, titanium.

18. An electrospun fiber obtained from a method according to any one of claims 1 to 15.

19. An electrospun fiber comprising potassium niobate and a polymer.

20. The fiber according to any one of claim 18 or 19, wherein the length of each fiber is about or greater than 500 μm, and the average diameter of the fiber is between 100 nm to 500 nm.

21. A humidity sensor device comprising fibers according to any one of claim 18 or 19.

22. The device according to claim 22, wherein the fibers are composed of densely stacked grains of about 40 nm in size.

23. The device according to claim 22, further comprising a substrate for supporting the fibers.

24. The device according to claim 24, wherein the substrate is SiO2/Si.

25. The device according to claim 25, wherein the thickness of the SiO2/Si substrate is about 2 μm and 285 nm respectively.

26. The device according to claim 22, wherein a metal is spluttered on top of the fibers to form interdigitated electrodes.

27. The device according to claim 27, wherein the interdigitated electrodes are spaced about 250 μm apart.

28. The device according to claim 27, wherein the metal layer is about 350 nm.

29. The device according to claim 28, wherein the metal is any one selected from the group comprising: aluminium, chromium, gold, molybdenum, platinum, silver, titanium.

30. The device according to claim 21, wherein the length of each fiber is about or greater than 500 μm.

31. The device according to claim 21, wherein the average diameter of the nanofiber is between 100 nm to 500 nm.

32. The device according to claim 21, wherein the fibers are stacked along the direction of the fiber axis.

33. The device according to claim 21, wherein the sensor is adapted to measure relative humidity of between 15-95% in atmospheric air at a room temperature of about 25° C.
